(19) United States
(12) Patent Application Publication
(10) Pub. No.: US 2026/0025920 A1
(43) Pub. Date: Jan. 22, 2026

(54) CIRCUIT BOARD STRUCTURE

(71) Applicant: UNIMICRON TECHNOLOGY CORP., Taoyuan City (TW)

(72) Inventors: Chun-Jen CHEN, Taoyuan City (TW); Chi-Hai KUO, Taoyuan City (TW); Pu-Ju LIN, Taoyuan City (TW); Cheng-Ta KO, Taoyuan City (TW)

(73) Assignee: UNIMICRON TECHNOLOGY CORP., Taoyuan City (TW)

(21) Appl. No.: 18/885,860

(22) Filed: Sep. 16, 2024

(30) Foreign Application Priority Data
Jul. 22, 2024 (TW) 113127309

(51) Int. Cl. H05K 1/09; H05K 1/03

(52) U.S. Cl. CPC H05K 1/09; H05K 1/0306

(57) ABSTRACT

A circuit board structure is provided. The circuit board structure includes a base layer, a redistribution layer, a copper layer, and a first molybdenum layer. The redistribution layer penetrates the base layer and has a first end and a second end. The copper layer is disposed on the first end of the redistribution layer. The first molybdenum layer is disposed on the copper layer or the second end of the redistribution layer.

### CROSS REFERENCE TO RELATED APPLICATIONS

This application claims priority of Taiwan Patent Application No. 113127309, filed on Jul. 22, 2024, the entirety of which is incorporated by reference herein.

### BACKGROUND OF THE INVENTION

### Field of the Invention

The present disclosure relates to circuit board structures, and, in particular, to a circuit board structure using a molybdenum layer as a protective layer.

### Description of the Related Art

One or more temporary substrates can be used as carriers to sequentially process both sides of a circuit board structure during the process of manufacturing the circuit board structure. In order to prevent the circuit pattern from being oxidized during the above-mentioned processing, protective layers are usually provided on both sides of the circuit board structure. Furthermore, after the circuit board structure is processed, these protective layers can be removed using an etching process. However, the above-mentioned processing is cumbersome, time-consuming, and costly. Therefore, although existing circuit board structures have largely met their intended purposes, they do not meet requirements in all respects. Therefore, there is still a need to develop new circuit board structures and manufacturing methods thereof.

### BRIEF SUMMARY OF THE INVENTION

In some embodiments, a circuit board structure is provided. The circuit board structure includes a base layer, a redistribution layer, a copper layer, and a first molybdenum layer. The redistribution layer penetrates the base layer and has a first end and a second end. The copper layer is disposed on the first end of the redistribution layer. The first molybdenum layer is disposed on the copper layer or the second end of the redistribution layer.

In some embodiments, the copper layer includes copper (Cu), and the weight percentage (wt %) of copper is greater than or equal to 99 wt %.

In some embodiments, the first molybdenum layer includes molybdenum (Mo), and the weight percentage (wt %) of molybdenum is greater than or equal to 80 wt %.

In some embodiments, the first molybdenum layer further includes tantalum (Ta), and the weight percentage (wt %) of tantalum is greater than or equal to 5 wt %.

In some embodiments, the first molybdenum layer further includes niobium (Ni), and the weight percentage (wt %) of niobium is greater than or equal to 2 wt %.

In some embodiments, the first molybdenum layer is disposed on the copper layer.

In some embodiments, the circuit board structure further includes a carrier, wherein the first molybdenum layer is between the copper layer and the carrier.

In some embodiments, the carrier is a glass substrate.

In some embodiments, the first molybdenum layer is coplanar with the surface of the base layer.

In some embodiments, the thickness of the base layer is between 1 μm and 200 μm, the thickness of the first molybdenum layer is between 5 nm and 1000 nm, and the thickness of the copper layer is between 5 nm to 1000 nm.

In some embodiments, the circuit board structure further includes a second molybdenum layer, wherein the second molybdenum layer is disposed on the second end of the redistribution layer.

In some embodiments, the second molybdenum layer includes molybdenum (Mo), and the weight percentage (wt %) of molybdenum is greater than or equal to 80 wt %.

In some embodiments, the second molybdenum layer further includes tantalum (Ta), and the weight percentage (wt %) of tantalum is greater than or equal to 5 wt %.

In some embodiments, the second molybdenum layer further includes niobium (Ni), and the weight percentage (wt %) of niobium is greater than or equal to 2 wt %.

In some embodiments, the second molybdenum layer is not coplanar with the surface of the base layer.

In some embodiments, the first molybdenum layer is disposed on the second end of the redistribution layer.

In some embodiments, the circuit board structure further includes a titanium layer, wherein the titanium layer is disposed on the copper layer.

In some embodiments, the titanium layer includes titanium (Ti), and the weight percentage (wt %) of titanium is greater than or equal to 99 wt %.

In some embodiments, the circuit board structure further includes a carrier, wherein the titanium layer is between the copper layer and the carrier.

In some embodiments, the carrier is a glass substrate.

The circuit board structure of the present disclosure can be applied in a variety of electronic devices. In order to make the features and advantages of the present disclosure more comprehensible, various embodiments are specially cited hereinafter, together with the accompanying drawings, to be described in detail as follows.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1 to 4 are respectively schematic cross-sectional views showing the circuit board structure at different stages during the manufacturing process according to some embodiments of the present disclosure.

FIGS. 5 to 11 are respectively schematic cross-sectional showing the circuit board structure at different stages during the subsequent manufacturing process according to some embodiments of the present disclosure.

FIGS. 12 to 16 are respectively schematic cross-sectional views showing the circuit board structure at different stages during the manufacturing process according to other embodiments of the present disclosure.

FIG. 17 is a schematic cross-sectional view showing the circuit board structure according to further embodiments of the present disclosure.

### DETAILED DESCRIPTION OF THE INVENTION

The devices of various embodiments of the present disclosure will be described in detail hereinafter. It should be understood that the following description provides many different embodiments for implementing various aspects of some embodiments of the present disclosure. The specific elements and arrangements described hereinafter are merely to clearly describe some embodiments of the present disclosure. Of course, these are only used as examples rather than limitations of the present disclosure. Furthermore, similar or corresponding reference numerals may be used in different embodiments to designate similar or corresponding elements in order to clearly describe the present disclosure. However, the use of these similar or corresponding reference numerals is only for the purpose of simply and clearly description of some embodiments of the present disclosure, and does not imply any correlation between the different embodiments or structures discussed.

In addition, it should be understood that ordinal numbers such as “first”, “second”, and the like used in the description and claims are used to modify elements and are not intended to imply and represent the element(s) have any previous ordinal numbers, and do not represent the order of a certain element and another element, or the order of the manufacturing method, and the use of these ordinal numbers is only used to clearly distinguished an element with a certain name and another element with the same name. The claims and the specification may not use the same terms, for example, a first element in the specification may be a second element in the claim.

In some embodiments of the present disclosure, terms related to bonding and connection, such as “connect”, “interconnect”, “bond”, and the like, unless otherwise defined, may refer to two structures in direct contact, or may also refer to two structures not in direct contact, that is there is another structure disposed between the two structures. Moreover, the terms related to bonding and connection can also include embodiments in which both structures are movable, or both structures are fixed. Furthermore, the terms “electrically connected” or “electrically coupled” include any direct and indirect means of electrical connection.

Herein, the terms “approximately”, “about”, and “substantially” generally mean within 10%, within 5%, within 3%, within 2%, within 1%, or within 0.5% of a given value or range. The given value is an approximate value, that is, “approximately”, “about”, and “substantially” can still be implied without the specific description of “approximately”, “about”, and “substantially”. The phrase “a range between a first value and a second value” means that the range includes the first value, the second value, and other values in between. Furthermore, any two values or directions used for comparison may have certain tolerance. If the first value is equal to the second value, it implies that there may be a tolerance within about 10%, within 5%, within 3%, within 2%, within 1%, or within 0.5% between the first value and the second value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

It should be understood that, in the following embodiments, features in several different embodiments may be replaced, recombined, and bonded to complete other embodiments without departing from the spirit of the present disclosure. The features of the various embodiments can be used in any combination as long as they do not violate the spirit of the present disclosure or conflict with each other.

Unless otherwise defined, all terms (including technical and scientific terms) used herein have the same meaning as commonly understood by a person of ordinary skills in the art. It is understood that these terms, such as those defined in commonly used dictionaries, should be interpreted as having meanings consistent with the relevant art and the background or context of the present disclosure, and should not be interpreted in an idealized or overly formal manner, unless otherwise defined in the embodiments of the present disclosure.

In the manufacturing process of existing circuit board structures, metals with strong chemical stability and/or structural stability are usually used as protective layers for circuit patterns to protect the circuit patterns from being oxidized during the processing of circuit board structures. However, these protective layers, while sufficiently protective, are not easily removed. As a result, an etching process may be used to ensure complete removal of these metals that have strong chemical stability and structural stability. In addition, in order to facilitate subsequent processing, the etched circuit board structure may need to be surface treated. In other words, although using a metal with strong chemical stability and/or structural stability as a protective layer can effectively protect the circuit board structure, it will also lead to complicated processes and higher production costs. To this end, the present disclosure provides a circuit board structure that uses molybdenum (Mo) as a protective layer to avoid oxidation of the circuit pattern of the circuit board structure and can effectively reduce the number of processes and production costs.

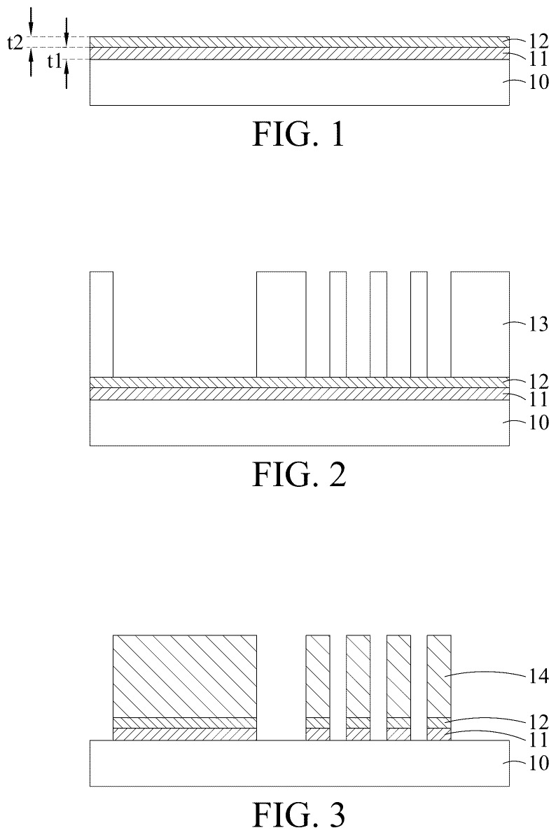

FIGS. 1 to 4 are schematic cross-sectional views showing the circuit board structures at different stages during the manufacturing process according to some embodiments of the present disclosure. It should be noted that, for the sake of simplicity and ease of understanding, the sizes of components (for example, the first molybdenum layer 11, the copper layer 12, the redistribution layer 14, the second molybdenum layer 21, the titanium layer 22 or the first molybdenum layer 23) and their proportions in the drawings of the present disclosure may be exaggerated. In addition, some components in the circuit board structure in the drawings of the present disclosure may be omitted, but a person having ordinary skill in the art can understand that the circuit board structure may further include other common components.

As shown in FIG. 1, the carrier 10 is provided, which is used to carry components disposed thereon (for example, the first molybdenum layer 11, the copper layer 12, and the redistribution layer 14 mentioned hereinafter, etc.) during the manufacturing process. In some embodiments, the material of the carrier 10 may be or may include: Group IV elements or Group IV compounds, such as silicon (Si), diamond (C), or silicon carbide (SiC); Group III-V compounds, such as nitrogen Gallium (GaN), aluminum gallium nitride (AlGaN), aluminum nitride (AlN), gallium phosphide (GaP), gallium arsenide (GaAs), or aluminum gallium arsenide (AlGaAs); other suitable materials; or a combination thereof, but the present disclosure is not limited thereto. In some embodiments, the material of the carrier 10 may be or include glass, quartz, sapphire, ceramics, other suitable materials, or a combination thereof, but the present disclosure is not limited thereto. In some embodiments, the material of the carrier 10 may be or may include polyimide (PI), polycarbonate (PC), polyethylene terephthalate (PET), polypropylene (PP), other suitable materials, or a combination thereof, but the present disclosure is not limited thereto. In this embodiment, the carrier 10 may be a glass substrate.

As shown in FIG. 1, following the above steps, the first molybdenum layer 11 is disposed on the carrier 10. Specifically, the first molybdenum layer 11 is used to protect the copper layer 12 or the redistribution layer 14 disposed thereon in subsequent processes and may be removed by applying flux in subsequent processes. Detailed description may be found hereinafter. In some embodiments, the first molybdenum layer 11 may be formed by a sputtering process, an evaporation process, other suitable processes, or a combination thereof, but the present disclosure is not limited thereto. In this embodiment, the first molybdenum layer 11 is disposed on the carrier 10 through a sputtering process.

In some embodiments, the first molybdenum layer 11 includes molybdenum, and the weight percentage (wt %) of molybdenum may be greater than or equal to 80 wt %, but the present disclosure is not limited thereto. For example, the weight percentage of molybdenum may be 80 wt %, 85 wt %, 87.5 wt %, 90 wt %, 92.5 wt %, 95 wt %, 97.5 wt %, or any value or range between the above values. In some embodiments, a molybdenum alloy target may be used as a raw material to form the first molybdenum layer 11. For example, a molybdenum-tantalum alloy (with 10.7 wt % of tantalum (Ta)), a molybdenum-niobium alloy (with 5 wt % of niobium (Nb)), other similar alloys, or a combination thereof may be used, but the present disclosure is not limited thereto. In other words, the first molybdenum layer 11 may include a small amount or a trace amount of other elements instead of only consisting of molybdenum element.

In some embodiments, the thickness t1 of the first molybdenum layer 11 may be between 5 nm and 1000 nm, but the present disclosure is not limited thereto. For example, the thickness t1 may be 5 nm, 10 nm, 50 nm, 100 nm, 200 nm, 500 nm, 750 nm, 1000 nm, or any value or range between the above values. In this embodiment, the thickness t1 is 50 nm.

As shown in FIG. 1, following the above steps, the copper layer 12 is disposed on the first molybdenum layer 11. Specifically, the copper layer 12 is used as a seed layer for the redistribution layer 14 in subsequent processes to facilitate the growth of the redistribution layer 14. In some embodiments, the copper layer 12 may be formed by a sputtering process, an evaporation process, other suitable processes, or a combination thereof, but the present disclosure is not limited thereto. In this embodiment, the copper layer 12 is disposed on the first molybdenum layer 11 through a sputtering process.

In some embodiments, the copper layer 12 includes copper (Cu), and the weight percentage of copper may be greater than or equal to 99.0 wt %, but the present disclosure is not limited thereto. For example, the weight percentage of copper may be 99.00 wt %, 99.20 wt %, 99.50 wt %, 99.75 wt %, 99.90 wt %, 99.99 wt %, 99.999 wt %, 99.9999 wt %, or any value or range between the above values. Alternatively, the copper layer 12 may consist essentially of copper and no other components. That is, without considering impurities, the copper layer 12 may be substantially composed of copper.

In some embodiments, the thickness t2 of the copper layer 12 may be between 5 nm and 1000 nm, but the present disclosure is not limited thereto. For example, the thickness t2 may be 5 nm, 10 nm, 50 nm, 100 nm, 200 nm, 500 nm, 750 nm, 1000 nm, or any value or range between the above values. In this embodiment, the thickness t2 is 300 nm.

As shown in FIG. 2, following the above steps, the mask layer 13 is disposed on the copper layer 12. Specifically, the mask layer 13 covers a part of the copper layer 12 and exposes another part of the copper layer 12. In some embodiments, the mask layer 13 may be formed by photolithography, but the present disclosure is not limited thereto. For example, the photolithography process may include photoresist coating (e.g., spin-on coating), soft baking, mask aligning, exposure, post-exposure baking, photoresist developing, rinsing, drying (for example, spin-drying and/or hard baking), other suitable lithography technology, and/or a combination thereof.

In some embodiments, the mask layer 13 may include a hard mask, a soft mask, or a combination thereof. For example, the material of the mask layer 13 may be or include silicon oxide, silicon nitride, silicon carbide, silicon oxycarbide, photoresist, other suitable materials, or a combination thereof, but the present disclosure is not limited thereto. In this embodiment, the mask layer 13 is photoresist.

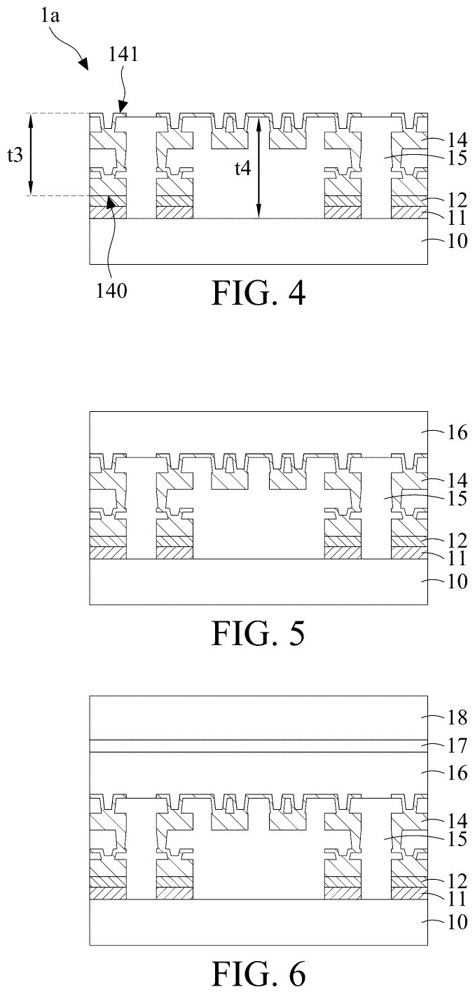

As shown in FIG. 3, following the above steps, the redistribution layer 14 is disposed on the copper layer 12 exposed from the mask layer 13. Specifically, the redistribution layer 14 is used to form electrical connection between both sides of the subsequently formed circuit board structure. It should be noted that although the structure of the redistribution layer 14 shown in FIG. 3 is a large-area sheet or an upwardly extending columnar shape, the present disclosure is not limited thereto. The specific shape, size, and configuration of the redistribution layer 14 may be adjusted by a person having ordinary skill in the art according to design requirements (for example, be adjusted to the structure as shown in FIG. 4). In some embodiments, the redistribution layer 14 may be formed by electroplating, electroless plating, other suitable processes, or a combination thereof, but the present disclosure is not limited thereto. In this embodiment, the redistribution layer 14 is disposed on the copper layer 12 through an electroplating process.

In some embodiments, the material of the redistribution layer 14 may be or include aluminum (Al), copper, alloys, or a compound thereof, but the present disclosure is not limited thereto. For example, the copper alloy or compound may be or include brass, phosphor bronze, beryllium copper, or oxygen-free copper, but the present disclosure is not limited thereto. In some embodiments, the material of the redistribution layer 14 may be similar or the same as the material of the copper layer 12, but the present disclosure is not limited thereto.

As shown in FIG. 3, following the above steps, the mask layer 13 is removed to expose the copper layer 12. In some embodiments, when the mask layer 13 includes silicon oxide, silicon nitride, silicon carbide, or silicon oxycarbide, the mask layer 13 may be removed by dry etching, wet etching, or a combination thereof, but the present disclosure is limited thereto. Alternatively, when the mask layer 13 includes photoresist, the mask layer 13 may be removed by heating, illumination, or a combination thereof, but the present disclosure is not limited thereto.

As shown in FIG. 3, following the above steps, the copper layer 12 not covered by the redistribution layer 14 and the first molybdenum layer 11 thereunder are removed to expose the carrier 10. In some embodiments, the copper layer 12 and the first molybdenum layer 11 thereunder may be removed by dry etching, wet etching, or a combination thereof, but the present disclosure is not limited thereto. In some embodiments, the mask layer 13, the copper layer 12, and the first molybdenum layer 11 may be removed at one time through the same removal process, but the present disclosure is not limited thereto. Alternatively, the mask layer 13, the copper layer 12, and the first molybdenum layer 11 may be removed respectively through different removal processes.

As shown in FIG. 4, following the above steps, the base layer 15 is disposed on the carrier 10. In some embodiments, the base layer 15 may be formed by a lamination process, a coating process, other suitable processes, or a combination thereof, but the present disclosure is not limited thereto. In some embodiments, the base layer 15 may include multiple sub-layers, and similar or identical processes or materials may be used to form each sub-layer. In some embodiments, the material of the base layer 15 may be or may include epoxy, polyimide, build-up film material (Ajinomoto buildup film, ABF), other suitable polymer materials, or a combination thereof, but the present disclosure is not limited thereto.

In some embodiments, the steps of disposing the mask layer 13, disposing the redistribution layer 14, removing the mask layer 13, and disposing the base layer 15 may be performed repeatedly. For example, a coating process, a photolithography process, a plating process, an etching process, other suitable processes, or a combination thereof may be repeatedly performed to form the redistribution layer 14 and the base layer 15 as shown in FIG. 4. In this way, the circuit board structure 1a may be obtained.

In this embodiment, the circuit board structure 1a includes the carrier 10, the first molybdenum layer 11, the copper layer 12, the redistribution layer 14, and the base layer 15. Specifically, the redistribution layer 14 is disposed in the base layer 15 and has the first end 140 and the second end 141. The copper layer 12 is disposed on the first end 140 of the redistribution layer 14. The first molybdenum layer 11 is disposed on the copper layer 12 and is coplanar with the surface (i.e., the lower surface) of the base layer 15. In the present disclosure, by making the first molybdenum layer 11 cover the copper layer 12 and positioning the first molybdenum layer 11 between the copper layer 12 and the carrier 10, the copper layer 12 may be effectively protected from being oxidized (because the carrier 10 will be removed in subsequent processes). It should be noted that the specific configuration (e.g., the component size, the component ratio, or the component shape) of the circuit board structure 1a shown in FIG. 4 is only an example, and the present disclosure is not limited thereto.

In some embodiments, the thickness t3 of the redistribution layer 14 may be between 1 μm and 200 μm, but the present disclosure is not limited thereto. For example, the thickness t3 may be 1 μm, 5 μm, 10 μm, 50 μm, 100 μm, 150 μm, 200 nm, or any value or range between the above values. In some embodiments, the redistribution layer 14 may have a non-pillar structure, for example, the structure as shown in FIG. 4. In this case, the thickness t3 of the redistribution layer 14 refers to the extension length of the redistribution layer 14 along the normal direction of the circuit board structure 1a (for example, the vertical direction shown in FIG. 4).

In some embodiments, the thickness t4 of the base layer 15 may be between 1 μm and 200 μm, but the present disclosure is not limited thereto. For example, the thickness t4 may be 1 μm, 5 μm, 10 μm, 50 μm, 100 μm, 150 μm, 200 nm, or any value or range between the above values. In some embodiments, the thickness t4 of the base layer 15 may be slightly smaller than the thickness t3 of the redistribution layer 14. In other words, the first end 140 of the redistribution layer 14 may be non-coplanar with the base layer 15.

In the above, possible formation methods of the circuit board structure 1a have been disclosed. In the following, the subsequent manufacturing process of the circuit board structure 1a will be further described to make the beneficial effects of the present disclosure clearer and easier to understand. FIGS. 5 to 11 are schematic cross-sectional views showing the circuit board structure at different stages in subsequent processes according to some embodiments of the present disclosure.

As shown in FIG. 5, in subsequent processes, the molding layer 16 is disposed on the side of the base layer 15 of the circuit board structure 1a away from the carrier 10. In some embodiments, the material of the molding layer 16 may be or may include epoxy, fillers, and additives, but the present disclosure is not limited thereto. Among them, the material of the filler may be or may include silica. As shown in FIG. 6, following the above steps, the adhesive layer 17 and the carrier 18 are disposed on the molding layer 16. In some embodiments, the material of the carrier 18 may be or may include: Group IV elements or Group IV compounds, Group III-V compounds, glass, quartz, sapphire, ceramics, polyimide, polycarbonate, polyethylene phthalate, polypropylene, other suitable materials, or a combination thereof, but the present disclosure is not limited thereto. In this embodiment, the carrier 18 is a glass substrate.

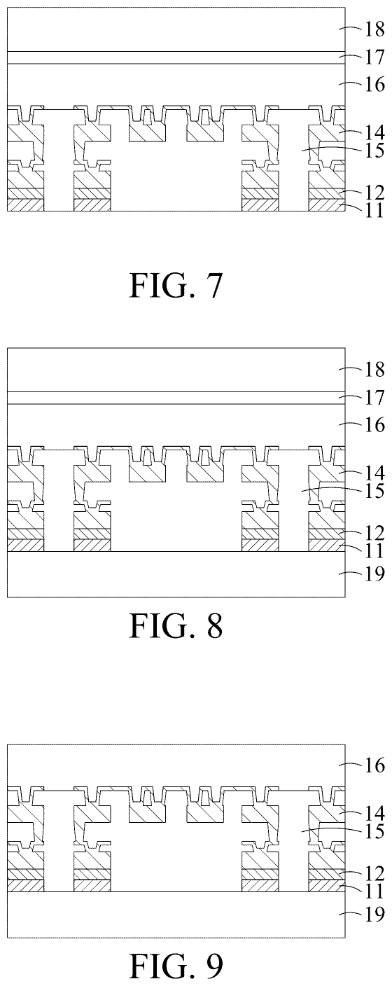

As shown in FIG. 7, following the above steps, the carrier 10 is removed to expose the first molybdenum layer 11 and the base layer 15. In some embodiments, the carrier 10 may be removed by a physical method, a chemical method, or a combination thereof, but the present disclosure is not limited thereto. For example, the physical method includes destroying, stripping, cutting, or other suitable methods, and the chemical method includes wet etching, dry etching, or other suitable methods.

It should be noted that since the carrier 10 is removed, the first molybdenum layer 11 may be used as a protective layer to protect the copper layer 12 from being oxidized. Specifically, the first molybdenum layer 11 may react with oxygen to form volatile molybdenum oxide. In this case, the formed molybdenum oxide will gradually sublime to prevent oxygen from further entering the copper layer 12. In this way, the process margin may be effectively improved, thereby avoiding oxidation of the copper layer 12 before being bonded to other electronic devices as much as possible.

As shown in FIG. 8, following the above steps, the carrier 19 is disposed on the first molybdenum layer 11 and the base layer 15. In some embodiments, the carrier 19 may be a blue tape. As shown in FIG. 9, following the above steps, the adhesive layer 17 and the carrier 18 are removed to expose the molding layer 16. In some embodiments, the carrier 18 may be removed by heating, illuminating, or directly tearing off the adhesive layer 17, but the present disclosure is not limited thereto.

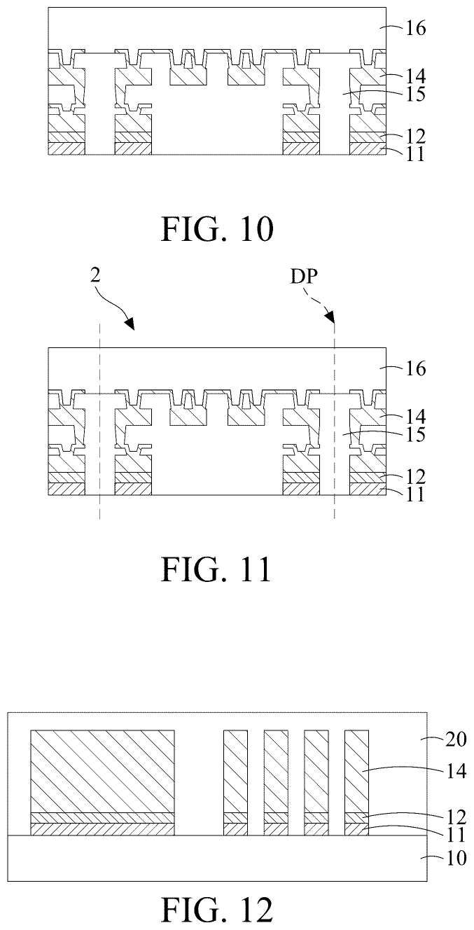

As shown in FIG. 10, following the above steps, the carrier 19 is removed to expose the first molybdenum layer 11 and the base layer 15. In some embodiments, the carrier 19 may be removed by directly tearing off, but the present disclosure is not limited thereto. As shown in FIG. 11, following the above steps, the cutting process DP may be performed on the structure shown in the figure to form multiple circuit board structures 2, wherein each circuit board structure 2 includes the first molybdenum layer 11, the copper layer 12, the redistribution layer 14, the base layer 15, and the molding layer 16. These circuit board structures 2 may be electrically connected to other electronic devices (not shown) through connectors such as solder balls.

It should be noted that before the circuit board structure 2 is bonded to other electronic devices, the first molybdenum layer 11 may be removed by applying flux. Specifically, flux is generally used to remove surface impurities (e.g., oxides) of the object to be soldered (e.g., the copper layer 12) to obtain a clean soldering surface, and the main components of the flux include “acids” and “salts” that are corrosive. In the case where the present disclosure uses molybdenum as the protective layer (i.e., the first molybdenum layer 11), the molybdenum may be removed directly by applying flux at the temperature of the soldering process. In other words, compared with the method of using other metals to protect the copper layer 12 in the prior art, the present disclosure may omit the step of etching other metal protective layers and may further omit the step of surface treatment of the copper layer 12. In this way, the present disclosure may effectively save the number of processes required for subsequent processing of the circuit board structure 1a (or the circuit board structure 2), thereby effectively reducing production costs.

In addition, in the case where molybdenum itself does not react with tin (Sn) or copper (e.g., forming an intermetallic compound), even the flux may not completely remove the first molybdenum layer 11, but the remaining molybdenum does not affect the bonding between the copper layer 12 and the solder ball. In this way, the manufacturing process of the present disclosure also effectively improves the structural stability and electrical stability of the circuit board structure.

FIGS. 12 to 16 are schematic cross-sectional views showing the circuit board structure at different stages of the manufacturing process according to other embodiments of the present disclosure. Among them, FIG. 12 is a process step that is continued from FIG. 3, so the relevant description may refer to the previous section and be omitted here. As shown in FIG. 12, following the above steps, the mask layer 20 is disposed on the carrier 10. Specifically, the mask layer 20 blanketly covers the redistribution layer 14. In some embodiments, the mask layer 20 may be formed through a coating process, but the present disclosure is not limited thereto. In this embodiment, the mask layer 20 is photoresist, but the present disclosure is not limited thereto.

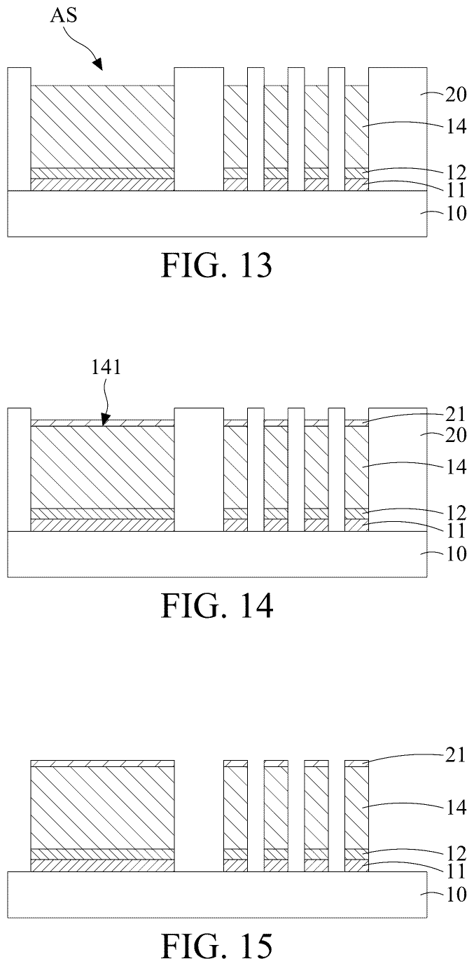

As shown in FIG. 13, following the above steps, a part of the mask layer 20 is removed to expose the upper surface of the redistribution layer 14. It should be noted that in this step, the upper surface of the mask layer 20 may be higher than the upper surface of the redistribution layer 14 so that the mask layer 20 and the redistribution layer 14 together form the accommodation space AS. Specifically, the accommodation space AS is used to provide a location for disposing the second molybdenum layer 21.

As shown in FIG. 14, following the above steps, the second molybdenum layer 21 is disposed in the accommodation space AS, wherein the second molybdenum layer 21 covers the redistribution layer 14. The difference from the embodiments of FIGS. 1 to 4 is that this embodiment is additionally provided with the second molybdenum layer 21 on the second end 141 of the redistribution layer 14. Similar to the first molybdenum layer 11, the second molybdenum layer 21 may also be removed by flux, and the residue thereof (if any) will not affect the bonding between the redistribution layer 14 and other electronic devices. In some embodiments, the second molybdenum layer 21 may not be removed, and the second molybdenum layer 21 may be directly electrically connected to other electronic devices.

In some embodiments, the second molybdenum layer 21 includes molybdenum, and the weight percentage of molybdenum may be greater than or equal to 80 wt %, but the present disclosure is not limited thereto. For example, the weight percentage of molybdenum may be 80 wt %, 85 wt %, 87.5 wt %, 90 wt %, 92.5 wt %, 95 wt %, 97.5 wt %, or any value or range between the above values. In some embodiments, a molybdenum alloy target may be used as a raw material to form the second molybdenum layer 21. For example, a molybdenum-tantalum alloy (with 10.7 wt % of tantalum (Ta)), a molybdenum-niobium alloy (with 5 wt % of niobium (Nb)), other similar alloys, or a combination thereof may be used, but the present disclosure is not limited thereto. In other words, the second molybdenum layer 21 may include a small amount or a trace amount of other elements instead of only consisting of molybdenum element. In some embodiments, the material of the second molybdenum layer 21 may be similar or identical to the material of the first molybdenum layer 11, but the present disclosure is not limited thereto.

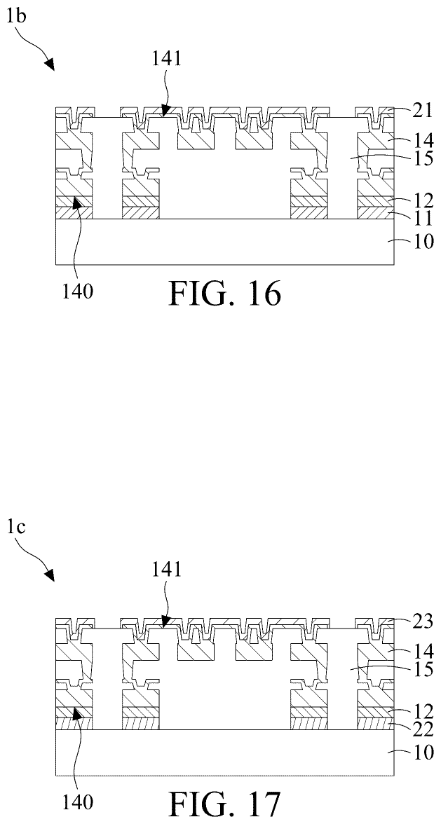

As shown in FIG. 15, the mask layer 20 is removed. In some embodiments, the mask layer 20 may be removed by heating, illumination, or a combination thereof, but the present disclosure is not limited thereto. As shown in FIG. 16, a coating process, a photolithography process, a plating process, an etching process, other suitable processes, or a combination thereof may be repeatedly performed to form the redistribution layer 14 and the base layer 15 as shown in FIG. 16. In this way, the circuit board structure 1b may be obtained.

In this embodiment, the circuit board structure 1b includes the carrier 10, the first molybdenum layer 11, the copper layer 12, the redistribution layer 14, the base layer 15, and the second molybdenum layer 21. Specifically, the first molybdenum layer 11 is disposed on the copper layer 12 and is coplanar with the surface (i.e., lower surface) of the base layer 15. In the present disclosure, by making the first molybdenum layer 11 cover the copper layer 12 and positioning the first molybdenum layer 11 between the copper layer 12 and the carrier 10, the copper layer 12 may be effectively protected from being oxidized (because the carrier 10 will be removed in subsequent processes).

On the other hand, the second molybdenum layer 21 is disposed on the second end 141 of the redistribution layer 14 and is non-coplanar with the surface (i.e., the upper surface) of the base layer 15. In the present disclosure, by making the second molybdenum layer 21 cover the second end 141 of the redistribution layer 14, the redistribution layer 14 may be effectively protected from being oxidized. It should be noted that the specific configuration (e.g., the component size, the component ratio, or the component shape) of the circuit board structure 1b shown in FIG. 16 is only an example, and the present disclosure is not limited thereto.

FIG. 17 is a schematic cross-sectional view showing the circuit board structure according to further embodiments of the present disclosure. As shown in FIG. 17, in some implementations of the present disclosure, titanium and molybdenum may be used as protective layers to protect both sides of the circuit board structure 1c. In this embodiment, the circuit board structure 1c includes the carrier 10, the titanium layer 22, the copper layer 12, the redistribution layer 14, the base layer 15, and the first molybdenum layer 23 (which may be similar to the second molybdenum layer 21). Specifically, the first molybdenum layer 23 is disposed on the second end 141 of the redistribution layer 14 and is non-coplanar with the surface (i.e., the upper surface) of the base layer 15. In the present disclosure, by making the first molybdenum layer 23 cover the second end 141 of the redistribution layer 14, the redistribution layer 14 may be effectively protected from being oxidized.

On the other hand, the titanium layer 22 is disposed on the copper layer 12 and is coplanar with the surface (i.e., lower surface) of the base layer 15. In the present disclosure, by making the titanium layer 22 cover the copper layer 12 and positioning the titanium layer 22 between the copper layer 12 and the carrier 10, the copper layer 12 may be effectively protected from being oxidized (because the carrier 10 will be removed in subsequent processes). It should be noted that the specific configuration (e.g., the component size, the component ratio, or the component shape) of the circuit board structure 1c shown in FIG. 17 is only an example, and the present disclosure is not limited thereto. By simultaneously using titanium and molybdenum as protective layers, the circuit pattern of the circuit board structure 1c may be effectively protected from being oxidized.

In some embodiments, the titanium layer 22 includes titanium, and the weight percentage of titanium may be greater than or equal to 99.0 wt %, but the present disclosure is not limited thereto. For example, the weight percentage of titanium may be 99.00 wt %, 99.20 wt %, 99.50 wt %, 99.75 wt %, 99.90 wt %, 99.99 wt %, 99.999 wt %, 99.9999 wt % or any value between the above values or scope. Alternatively, the titanium layer 22 may consist essentially of titanium and no other components. That is, without considering impurities, the titanium layer 22 may be substantially composed of titanium.

In some embodiments, the first molybdenum layer 23 includes molybdenum, and the weight percentage of molybdenum may be greater than or equal to 80 wt %, but the present disclosure is not limited thereto. For example, the weight percentage of molybdenum may be 80 wt %, 85 wt %, 87.5 wt %, 90 wt %, 92.5 wt %, 95 wt %, 97.5 wt %, or any value or range between the above values. In some embodiments, a molybdenum alloy target may be used as a raw material to form the first molybdenum layer 11. For example, a molybdenum-tantalum alloy (with 10.7 wt % of tantalum (Ta)), a molybdenum-niobium alloy (with 5 wt % of niobium (Nb)), other similar alloys, or a combination thereof may be used, but the present disclosure is not limited thereto. In other words, the first molybdenum layer 23 may include a small amount or a trace amount of other elements instead of only consisting of molybdenum element. In some embodiments, the material of the first molybdenum layer 23 may be similar or identical to the material of the first molybdenum layer 11 or the second molybdenum layer 21, but the present disclosure is not limited thereto.

In summary, the present disclosure provides a circuit board structure and its implementation. By using molybdenum as a protective layer, the circuit pattern may be effectively protected, while the process complexity (or the number of processes) may be reduced, thereby reducing production costs.

The foregoing outlines features of several embodiments of the present disclosure, so that a person of ordinary skill in the art may better understand the aspects of the present disclosure. A person of ordinary skill in the art should appreciate that, the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A circuit board structure, comprising:
a base layer;
a redistribution layer penetrating the base layer and having a first end and a second end;
a copper layer disposed on the first end of the redistribution layer; and
a first molybdenum layer disposed on the copper layer or on the second end of the redistribution layer.

2. The circuit board structure as claimed in claim 1, wherein the copper layer comprises copper (Cu), and a weight percentage (wt %) of copper is greater than or equal to 99 wt %.

3. The circuit board structure as claimed in claim 1, wherein the first molybdenum layer comprises molybdenum (Mo), and a weight percentage (wt %) of molybdenum is greater than or equal to 80 wt %.

4. The circuit board structure as claimed in claim 3, wherein the first molybdenum layer further comprises tantalum (Ta), and a weight percentage (wt %) of tantalum is greater than or equal to 5 wt %.

5. The circuit board structure as claimed in claim 3, wherein the first molybdenum layer further comprises niobium (Ni), and a weight percentage (wt %) of niobium is greater than or equal to 2 wt %.

6. The circuit board structure as claimed in claim 1, wherein the first molybdenum layer is disposed on the copper layer.

7. The circuit board structure as claimed in claim 6, further comprising a carrier, wherein the first molybdenum layer is between the copper layer and the carrier.

8. The circuit board structure as claimed in claim 7, wherein the carrier is a glass substrate.

9. The circuit board structure as claimed in claim 6, wherein the first molybdenum layer is coplanar with a surface of the base layer.

10. The circuit board structure as claimed in claim 6, wherein a thickness of the base layer is between 1 μm and 200 μm, a thickness of the first molybdenum layer is between 5 nm and 1000 nm, and a thickness of the copper layer is between 5 nm to 1000 nm.

11. The circuit board structure as claimed in claim 6, further comprising a second molybdenum layer, wherein the second molybdenum layer is disposed on the second end of the redistribution layer.

12. The circuit board structure as claimed in claim 11, wherein the second molybdenum layer comprises molybdenum (Mo), and a weight percentage (wt %) of molybdenum is greater than or equal to 80 wt %.

13. The circuit board structure as claimed in claim 12, wherein the second molybdenum layer further comprises tantalum (Ta), and a weight percentage (wt %) of tantalum is greater than or equal to 5 wt %.

14. The circuit board structure as claimed in claim 12, wherein the second molybdenum layer further comprises niobium (Ni), and a weight percentage (wt %) of niobium is greater than or equal to 2 wt %.

15. The circuit board structure as claimed in claim 11, wherein the second molybdenum layer is not coplanar with a surface of the base layer.

16. The circuit board structure as claimed in claim 1, wherein the first molybdenum layer is disposed on the second end of the redistribution layer.

17. The circuit board structure as claimed in claim 16, further comprising a titanium layer, wherein the titanium layer is disposed on the copper layer.

18. The circuit board structure as claimed in claim 17, wherein the titanium layer comprises titanium (Ti), and a weight percentage (wt %) of titanium is greater than or equal to 99 wt %.

19. The circuit board structure as claimed in claim 17, further comprising a carrier, wherein the titanium layer is between the copper layer and the carrier.

20. The circuit board structure as claimed in claim 19, wherein the carrier is a glass substrate.
